(19) United States
(12) Patent Application Publication
(10) Pub. No.: US 2025/0393293 A1
(43) Pub. Date: Dec. 25, 2025

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Hiroshi KONO, Himeji, Hyogo (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/311,055

(22) Filed: Aug. 27, 2025

Related U.S. Application Data
(63) Continuation of application No. PCT/JP2024/003664, filed on Feb. 5, 2024.

(30) Foreign Application Priority Data
Sep. 22, 2023 (JP) 2023-158370

(51) Int. Cl. H10D 84/00; H10D 62/10; H10D 62/832; H10D 84/01; H10D 84/03

(52) U.S. Cl. CPC H10D 84/146; H10D 62/127; H10D 62/8325; H10D 84/0109; H10D 84/035

(57) ABSTRACT

According to one embodiment, a semiconductor device includes first and second electrodes, first to fifth semiconductor regions, and a gate electrode. The first and third semiconductor regions are of a first conductivity type. The second, fourth, and fifth semiconductor regions are of a second conductivity type. The first semiconductor region includes first and second parts. The fourth semiconductor region is located on the second part and is positioned around the second semiconductor region. The second electrode includes first and second metal parts. The first metal part contacts the first part and the second semiconductor region. The second metal part contacts the second part and the fourth semiconductor region. The first and second metal parts include a first element selected from titanium, molybdenum, and vanadium. The fifth semiconductor region is located lower than the fourth semiconductor region and is positioned directly under the second metal part.

### CROSS-REFERENCE TO RELATED APPLICATIONS

This is a continuation application of International Patent Application PCT/JP2024/003664, filed on Feb. 5, 2024. This application also claims priority to Japanese Patent Application No. 2023-158370, filed on Sep. 22, 2023. The entire contents of which are incorporated herein by reference.

### FIELD

Embodiments of the invention relate generally to a semiconductor device.

### BACKGROUND

Semiconductor devices such as metal-oxide-semiconductor field-effect transistors (MOSFETs) and the like are used in applications such as power conversion and the like. It is desirable for the leakage current of such a semiconductor device to be low.

### BRIEF DESCRIPTION OF THE DRAWINGS

FIG. 1 is a plan view showing a semiconductor device according to an embodiment;

FIG. 2 is an enlarged plan view of part II of FIG. 1;

FIG. 3 is a III-III cross-sectional view of FIG. 2;

FIG. 4 is a IV-IV cross-sectional view of FIG. 2;

FIGS. 5A and 5B are cross-sectional views showing a method for manufacturing the semiconductor device according to the embodiment;

FIGS. 6A and 6B are cross-sectional views showing the method for manufacturing the semiconductor device according to the embodiment;

FIGS. 7A and 7B are cross-sectional views showing the method for manufacturing the semiconductor device according to the embodiment;

FIGS. 8A and 8B are plan views showing other examples of the semiconductor device according to the embodiment;

FIG. 9 is a cross-sectional view showing a portion of a semiconductor device according to a first modification of the embodiment;

FIG. 10 is a cross-sectional view showing a portion of a semiconductor device according to the first modification of the embodiment; and

FIG. 11 is a cross-sectional view showing a portion of a semiconductor device according to a second modification of the embodiment.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a gate electrode, a fourth semiconductor region of the second conductivity type, a second electrode, and a fifth semiconductor region of the second conductivity type. The first semiconductor region is located on the first electrode. The first semiconductor region includes a first part, and a second part located around the first part along a first plane perpendicular to a first direction. The first direction is from the first electrode toward the first part. The second semiconductor region is located on the first part. The third semiconductor region is located on the second semiconductor region. The gate electrode faces the second semiconductor region via a gate insulating layer. The fourth semiconductor region is located on the second part and is positioned around the second semiconductor region along the first plane. The second electrode includes a first metal part and a second metal part. The first metal part contacts the first part and the second semiconductor region and includes at least one type of first element selected from the group consisting of titanium, molybdenum, and vanadium. The second metal part contacts the second part and the fourth semiconductor region and includes at least one type of the first element. The second electrode is located on the second, third, and fourth semiconductor regions. The fifth semiconductor region is located lower than the fourth semiconductor region and is positioned directly under the second metal part.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following description, the notations of n⁺, n, n⁻, p⁺, p, and p⁻ indicate relative levels of the impurity concentrations of the conductivity types. Specifically, n⁺ indicates that the n-type impurity concentration is relatively higher than that of n; and n⁻ indicates that the n-type impurity concentration is relatively lower than that of n. p⁺ indicates that the p-type impurity concentration is relatively higher than that of p; and p⁻ indicates that the p-type impurity concentration is relatively lower than that of p. According to the embodiments below, each embodiment may be implemented by inverting the p-type and the n-type of the semiconductor regions.

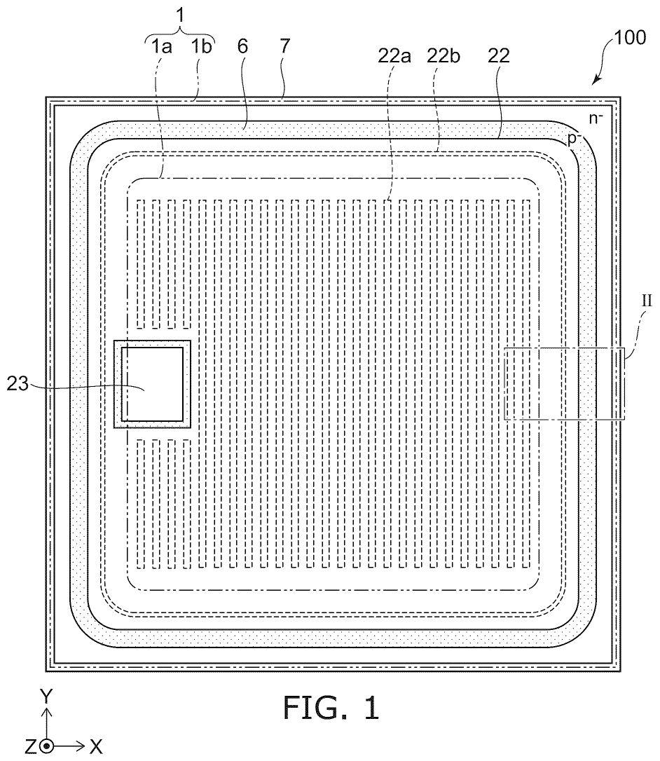

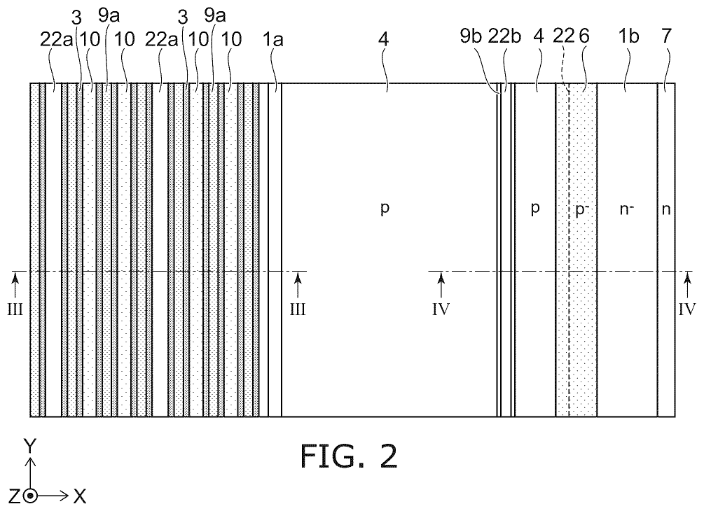

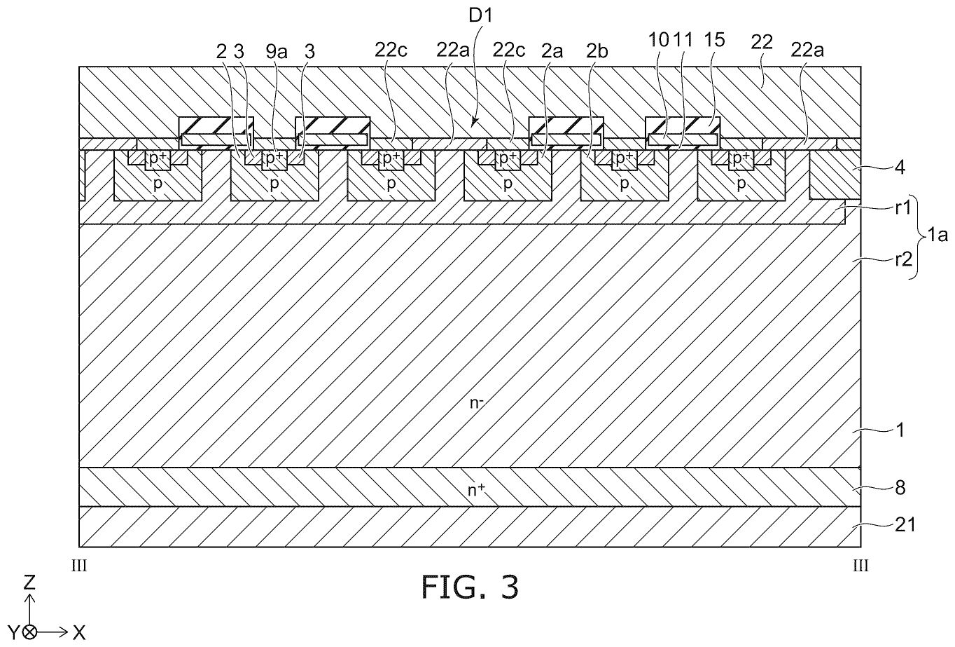

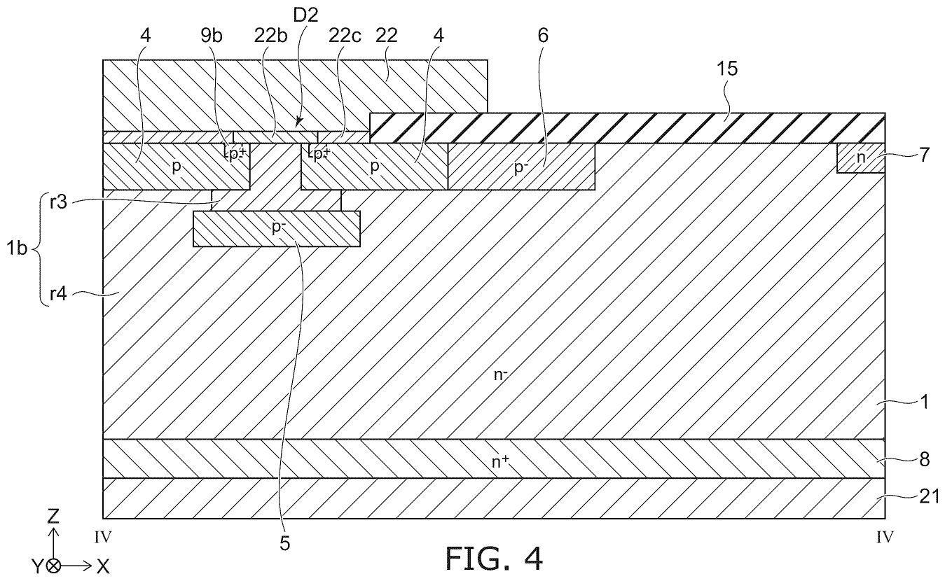

FIG. 1 is a plan view showing a semiconductor device according to an embodiment. FIG. 2 is an enlarged plan view of part II of FIG. 1. FIG. 3 is a III-III cross-sectional view of FIG. 2. FIG. 4 is a IV-IV cross-sectional view of FIG. 2.

The semiconductor device according to the embodiment is a MOSFET. As shown in FIGS. 1 to 4, the semiconductor device 100 according to the embodiment includes an n⁻-type (first-conductivity-type) drift region 1 (a first semiconductor region), a p-type (second-conductivity-type) base region 2 (a second semiconductor region), an n⁺-type source region 3 (a third semiconductor region), a p-type semiconductor region 4 (a fourth semiconductor region), a p⁻-type shield region 5 (a fifth semiconductor region), a p⁻-type RESURF region 6, an n-type semiconductor region 7, an n⁺-type drain region 8, a p⁺-type contact region 9a, a p⁺-type contact region 9b, a gate electrode 10, an insulating layer 15, a drain electrode 21 (a first electrode), a source electrode 22 (a second electrode), and a gate pad 23. The insulating layer 15 is not illustrated in FIG. 1. The insulating layer 15 and a portion of the source electrode 22 are not illustrated in FIG. 2.

An XYZ orthogonal coordinate system is used in the description of embodiments. The direction from the drain electrode 21 toward a part (a first part 1a) of the n⁻-type drift region 1 is referred to as a Z-direction (a first direction). Two mutually-orthogonal directions that are perpendicular to the Z-direction are referred to as an X-direction (a second direction) and a Y-direction (a third direction). In the description, the direction from the drain electrode 21 toward the n-type drift region 1 is referred to as “up/above”, and the opposite direction is referred to as “down/below”. These directions are based on the relative positional relationship between the drain electrode 21 and the n⁻-type drift region 1, and are independent of the direction of gravity.

As shown in FIG. 1, the source electrode 22 and the gate pad 23 are located at the upper surface of the semiconductor device 100. The source electrode 22 and the gate pad 23 are separated from each other.

As shown in FIG. 2, the n⁺-type source region 3, the p-type semiconductor region 4, the p⁻-type RESURF region 6, the p⁺-type contact region 9a, the p⁺-type contact region 9b, the gate electrode 10, etc., are located under the source electrode 22. The source electrode 22 is illustrated by a broken line in FIG. 2.

As shown in FIGS. 3 and 4, the drain electrode 21 is located at the lower surface of the semiconductor device 100. The n⁺-type drain region 8 is located on the drain electrode 21 and is electrically connected to the drain electrode 21. The n⁻-type drift region 1 is located on the n⁺-type drain region 8. The n-type impurity concentration of the n⁻-type drift region 1 is less 5 than the n-type impurity concentration of the n⁺-type drain region 8.

As illustrated by the double dot-dash lines in FIG. 1, the n⁻-type drift region 1 includes the first part 1a and a second part 1b. The first part 1a is positioned at the center of the n⁻-type drift region 1 in the X-Y plane (a first plane). The second part 10 1b is located around the first part 1a along the X-Y plane.

As shown in FIG. 3, the p-type base region 2 is located on the first part 1a. The n⁺-type source region 3 and the p⁺-type contact region 9a are selectively provided on the p-type base 15 region 2. The p-type impurity concentration of the p⁺-type contact region 9a is greater than the p-type impurity concentration of the p-type base region 2.

The gate electrode 10 faces a portion of the p-type base region 2 via a gate insulating layer 11 in the Z-direction. The gate electrode 10 is electrically connected to the gate pad 23. The gate electrode 10 and the source electrode 22 are electrically isolated from each other by the insulating layer 15.

Multiple p-type base regions 2, multiple n⁺-type source regions 3, multiple p⁺-type contact regions 9a, and multiple gate electrodes 10 are arranged in the X-direction. Each p-type base region 2, each n⁺-type source region 3, each p⁺-type contact region 9a, and each gate electrode 10 extend in the Y-direction.

As shown in FIG. 4, the p-type semiconductor region 4 is located on the second part 1b. The p-type semiconductor region 4 is positioned around the multiple p-type base regions 2 along the X-Y plane. The Y-direction end of the p-type base region 2 may be connected to the p-type semiconductor region 4. Multiple p-type semiconductor regions 4 are arranged in directions from the first part 1a toward the second part 1b. The multiple p-type semiconductor regions 4 are separated from each other. The spacing between the p-type semiconductor regions 4 is wider than the spacing between the p-type base regions 2 adjacent to each other in the X-direction.

The p⁺-type contact region 9b is selectively provided on the p-type semiconductor region 4. The p-type impurity concentration of the p⁺-type contact region 9b is greater than the p-type impurity concentration of the p-type semiconductor region 4.

The p⁻-type RESURF region 6 is located around the p-type semiconductor region 4 along the X-Y plane and contacts the p-type semiconductor region 4. The p-type impurity concentration of the p⁻-type RESURF region 6 is less than the p-type impurity concentration of the p-type semiconductor region 4. By including the p⁻-type RESURF region 6, the depletion layer can be spread further toward the outer perimeter of the semiconductor device 100; and the breakdown voltage of the semiconductor device 100 can be increased.

The n-type semiconductor region 7 is located around the p⁻-type RESURF region 6 along the X-Y plane, and is separated from the p⁻-type RESURF region 6. The n-type impurity concentration of the n-type semiconductor region 7 is greater than the n-type impurity concentration of the n⁻-type drift region 1. The n-type semiconductor region 7 is arranged along the outer perimeter of the semiconductor device 100. By including the n-type semiconductor region 7, the depletion layer that spreads toward the outer perimeter of the semiconductor device 100 can be prevented from reaching the end surface of the semiconductor device 100.

The source electrode 22 is positioned on the p-type base region 2, the n⁺-type source region 3, the p-type semiconductor region 4, the p⁺-type contact region 9a, and the p⁺-type contact region 9b, and is electrically connected to these semiconductor regions.

More specifically, the source electrode 22 includes a first metal part 22a and a second metal part 22b as shown in FIGS. 1 to 4. The first metal part 22a and the second metal part 22b are illustrated by broken lines in FIG. 1. The first metal part 22a is positioned on the first part 1a and contacts the first part 1a and the p-type base region 2. The second metal part 22b is positioned on the second part 1b and contacts the p-type semiconductor region 4 and the p⁺-type contact region 9b.

Multiple first metal parts 22a are arranged in the X-direction; and each first metal part 22a extends in the Y-direction. The second metal part 22b is located around the multiple gate electrodes 10 and the multiple first metal parts 22a along the X-Y plane.

As one specific example, one first metal part 22a and one or more gate electrodes 10 are alternately arranged in the X-direction as shown in FIG. 2. The multiple p-type base regions 2 include a p-type base region 2a and a p-type base region 2b. One X-direction end part of the p-type base region 2a faces the gate electrode 10; and the other end part of the p-type base region 2a contacts the first metal part 22a. The two X-direction end parts of the p-type base region 2b respectively face the two gate electrodes 10.

Schottky junctions are formed between the first part 1a and the first metal part 22a and between the second part 1b and the second metal part 22b. In other words, the semiconductor device 100 includes a Schottky barrier diode D1 made of the first part 1a and the first metal part 22a, and a Schottky barrier diode D2 made of the second part 1b and the second metal part 22b.

As shown in FIGS. 3 and 4, the source electrode 22 may further include a silicide region 22c. The silicide region 22c is not illustrated in FIG. 2. The silicide region 22c is located on the n⁺-type source region 3 and the p⁺-type contact region 9a and has ohmic contacts with the n⁺-type source region 3 and the p⁺-type contact region 9a.

The p⁻-type shield region 5 is located lower than the p-type semiconductor region 4 and is positioned directly under the second metal part 22b. More specifically, the multiple p-type semiconductor regions 4 are separated from each other with a portion of the second part 1b interposed. The second metal part 22b contacts the portion of the second part 1b. The p⁻-type shield region 5 is positioned under the portion of the second part 1b. The p--type shield region 5 is arranged in a ring shape along the second metal part 22b.

As shown in FIG. 3, the first part 1a may include a first region r1 and a second region r2. The first region r1 contacts the p-type base region 2 and the first metal part 22a. The first region r1 also may be located directly under the gate electrode 10. The second region r2 is positioned between the drain electrode 21 and the first region r1 in the Z-direction. The n-type impurity concentration of the first region r1 is greater than the n-type impurity concentration of the second region r2.

As shown in FIG. 4, the second part 1b may include a third region r3 and a fourth region r4. The third region r3 contacts the p-type semiconductor region 4, the p⁻-type shield region 5, and the second metal part 22b. The third region r3 is separated from the first region r1. The fourth region r4 is positioned between the drain electrode 21 and the third region r3 in the Z-direction. The n-type impurity concentration of the third region r3 is greater than the n-type impurity concentration of the fourth region r4.

Examples of the materials of the components will now be described.

The n⁻-type drift region 1, the p-type base region 2, the n⁺-type source region 3, the p-type semiconductor region 4, the p⁻-type shield region 5, the p⁻-type RESURF region 6, the n-type semiconductor region 7, the n⁺-type drain region 8, the p⁺-type contact region 9a, and the p⁺-type contact region 9b include silicon, silicon carbide, gallium nitride, or gallium arsenide as a semiconductor material. Silicon carbide is favorable as the semiconductor material. Nitrogen, arsenic, phosphorus, or antimony can be used as an n-type impurity. Aluminum or boron can be used as a p-type impurity.

The gate electrode 10 includes a conductive material such as polysilicon, etc. The gate insulating layer 11 and the insulating layer 15 include insulating materials such as silicon oxide, silicon nitride, silicon oxynitride, etc. The drain electrode 21 and the gate pad 23 include metal materials such as aluminum, etc.

The first metal part 22a and the second metal part 22b include at least one type of first element selected from the group consisting of titanium, molybdenum, and vanadium. By the first metal part 22a and the second metal part 22b including at least one type of the first element, Schottky junctions are formed between the first part 1a and the first metal part 22a and between the second part 1b and the second metal part 22b. The silicide region 22c includes nickel silicide. The part of the source electrode 22 other than the first metal part 22a, the second metal part 22b, and the silicide region 22c includes aluminum.

Operations of the semiconductor device 100 will now be described. A voltage that is not less than a threshold is applied to the gate electrode 10 in a state in which a voltage that is positive with respect to the source electrode 22 is applied to the drain electrode 21. As a result, a channel (an inversion layer) is formed in the p-type base region 2; and the semiconductor device 100 is set to an on-state. Electrons flow from the source electrode 22 toward the drain electrode 21 via the channel. When the voltage applied to the gate electrode 10 drops below the threshold, the channel in the p-type base region 2 disappears, and the semiconductor device 100 is switched to an off-state.

When the semiconductor device 100 is in the off-state, there are cases where a voltage that is positive with respect to the drain electrode 21 is applied to the source electrode 22. At this time, a current flows from the source electrode 22 to the drain electrode 21 via the Schottky barrier diodes D1 and D2.

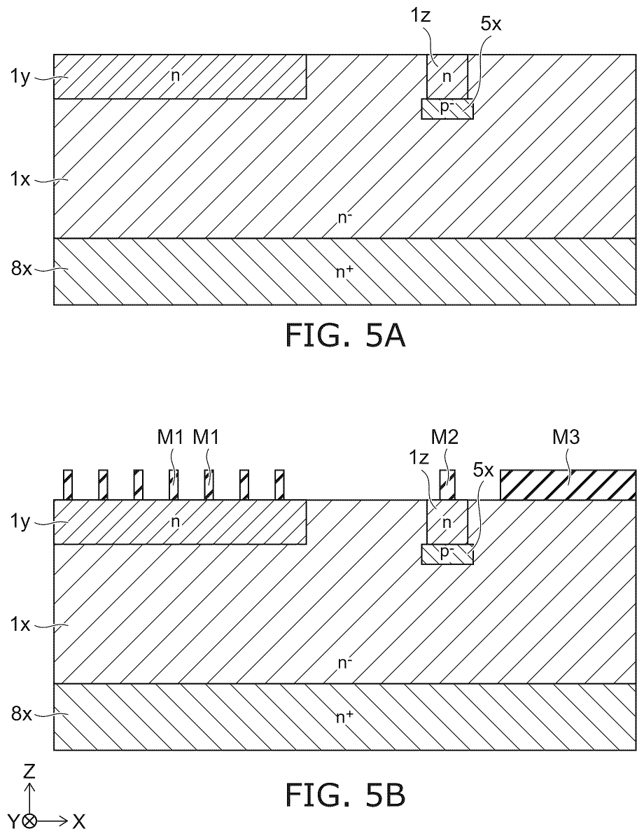

FIGS. 5A to 7B are cross-sectional views showing a method for manufacturing the semiconductor device according to the embodiment.

First, a semiconductor substrate that includes an n⁻-type semiconductor layer 1x and an n⁺-type semiconductor layer 8x is prepared. The n⁻-type semiconductor layer 1x is located on the n⁺-type semiconductor layer 8x. An n-type semiconductor region 1y, an n-type semiconductor region 1z, and a p⁻-type semiconductor region 5x are formed as shown in FIG. 5A by sequentially ion-implanting a p-type impurity and an n-type impurity into the upper surface of the n⁻-type semiconductor layer 1x. Or, the p⁻-type semiconductor region 5x may be formed by ion-implanting a p-type impurity into the upper surface of the n⁻-type semiconductor layer 1x, and then an n⁻-type semiconductor layer may be epitaxially grown. Then, the n-type semiconductor region 1y and the n-type semiconductor region 1z may be formed by selectively ion-implanting an n-type impurity into the n⁻-type semiconductor layer that is epitaxially grown. The n-type semiconductor region 1y 1 and the n-type semiconductor region 1z are separated from each other. The p⁻-type semiconductor region 5x is positioned under the n-type semiconductor region 1z.

A photoresist is formed on the n⁻-type semiconductor layer 1x, the n-type semiconductor region 1y, and the n-type semiconductor region 1z. The photoresist is patterned by photolithography and reactive ion etching (RIE). As a result, masks M1 to M3 are formed as shown in FIG. 5B. The masks M1 are formed on the n-type semiconductor region 1y. The positions of the masks M1 correspond to the positions of the gaps between the p-type base regions 2. The mask M2 is formed on the n-type semiconductor region 1z. The position of the mask M2 corresponds to the position of the gap between the p-type semiconductor regions 4. The mask M3 is formed on the outer perimeter part of the n⁻-type semiconductor layer 1x. For example, the width (the dimension in the X-direction) of the mask M2 is greater than the widths of the masks M1.

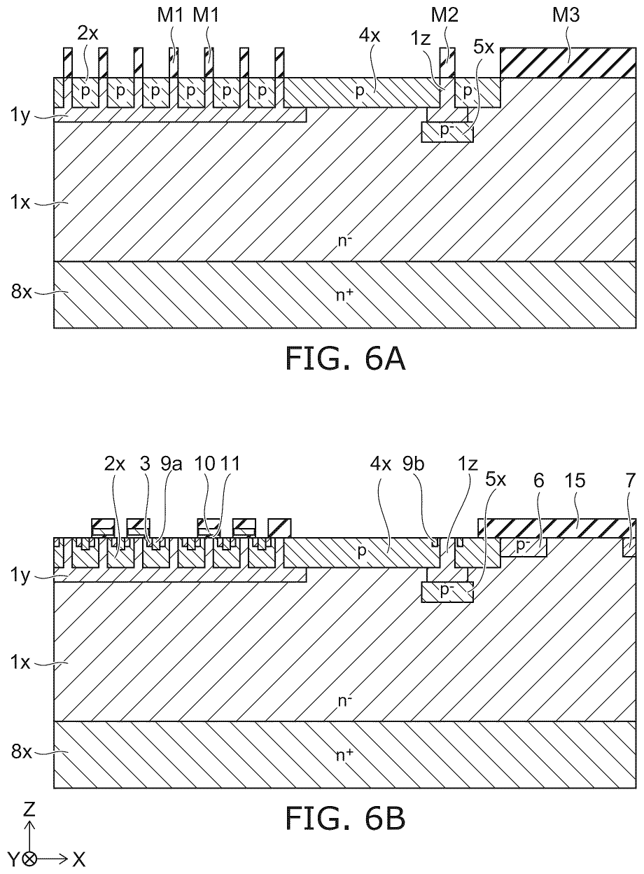

A p-type impurity is ion-implanted into the upper surfaces of the n⁻-type semiconductor layer 1x, the n-type semiconductor region 1y, and the n-type semiconductor region 1z. As shown in FIG. 6A, a p-type semiconductor region 2x and a p-type semiconductor region 4x are formed in the regions not covered with the masks M1 to M3.

After removing the masks M1 to M3, as shown in FIG. 6B, the n⁺-type source region 3, the p⁻-type RESURF region 6, the n-type semiconductor region 7, the p⁺-type contact region 9a, the p⁺-type contact region 9b, the gate electrode 10, the gate insulating layer 11, and the insulating layer 15 are formed. Known methods are applicable to the formation of these components.

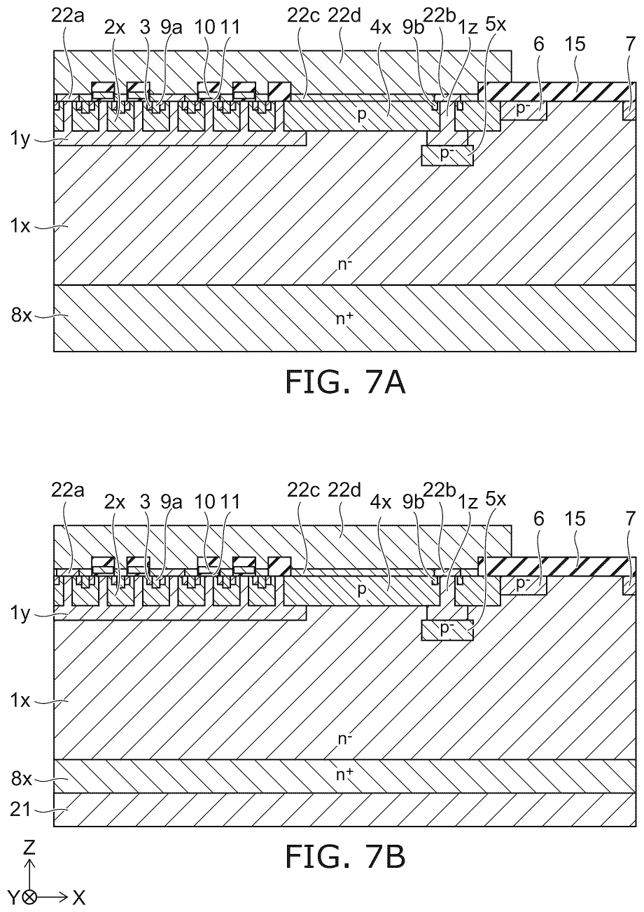

The first metal part 22a is formed on the n-type semiconductor region 1y; and the second metal part 22b is formed on the n-type semiconductor region 1z. The silicide region 22c is formed on the p-type base region 2, the n⁺-type source region 3, the p-type semiconductor region 4, the p⁺-type contact region 9a, and the p⁺-type contact region 9b. As shown in FIG. 7A, an aluminum layer 22d is formed on the first metal part 22a, the second metal part 22b, and the silicide region 22c.

The lower surface of the n⁺-type semiconductor layer 8x is polished until the n⁺-type semiconductor layer 8x has a prescribed thickness. As shown in FIG. 7B, the drain electrode 21 is formed at the polished lower surface of the n⁺-type semiconductor layer 8x. The semiconductor device 100 according to the embodiment is manufactured by the processes described above.

The n⁻-type semiconductor layer 1x shown in FIG. 7B corresponds to the second region r2 of the first part 1a and the fourth region r4 of the second part 1b shown in FIGS. 3 and 4. The n-type semiconductor region 1y corresponds to the first region r1 of the first part 1a. The n-type semiconductor region 1z corresponds to the third region r3 of the second part 1b. The p-type semiconductor region 2x corresponds to the p-type base region 2. The p-type semiconductor region 4x corresponds to the p-type semiconductor region 4. The p⁻-type semiconductor region 5x corresponds to the p⁻-type shield region 5. The n⁺-type semiconductor layer 8x corresponds to the n⁺-type drain region 8.

Advantages of the embodiment will now be described.

The semiconductor device 100 includes a parasitic diode made of the n⁻-type drift region 1 and the p-type base region 2, and a parasitic diode made of the n⁻-type drift region 1 and the p-type semiconductor region 4. A large amount of carriers is injected into the n⁻-type drift region 1 when these parasitic diodes operate. Therefore, reverse recovery takes a long period of time when the parasitic diodes operate. Also, the power loss is increased because a charge amount Qrr during reverse recovery is large.

For this problem, the semiconductor device 100 includes the Schottky barrier diodes D1 and D2. The forward voltages of the Schottky barrier diodes D1 and D2 are lower than the forward voltages of the parasitic diodes. Therefore, when a positive voltage is applied to the source electrode 22, the Schottky barrier diodes D1 and D2 operate before the parasitic diodes operate. An increase of the voltage of the source electrode 22 is suppressed when currents flow through the Schottky barrier diodes D1 and D2. Therefore, the parasitic diodes do not easily operate, and the power loss of the semiconductor device 100 can be reduced.

When, however, the Schottky barrier diodes D1 and D2 are included, leakage currents may flow via the Schottky barrier diodes D1 and D2 when the semiconductor device 100 is in the off-state. The power loss is increased when leakage currents flow in the semiconductor device 100. It is therefore desirable for the leakage currents due to the Schottky barrier diodes D1 and D2 to be small.

For the Schottky barrier diode D1, the leakage current can be sufficiently reduced by adjusting the dimensions and arrangement of the p-type base regions 2. For example, the leakage current due to the Schottky barrier diode D1 can be reduced by making the spacing between the p-type base regions 2 narrow and by reducing the contact area between the first part 1a and the first metal part 22a.

On the other hand, for the Schottky barrier diode D2, it is difficult to make the spacing between the p-type semiconductor regions 4 narrow. For example, the spacing between the p-type base regions 2 and the spacing between the p-type semiconductor regions 4 correspond respectively to the widths of the masks M1 and the width of the mask M2 shown in FIG. 5B. Many masks M1 are formed together on the first part 1a. On the other hand, only a small number of masks M2 are formed on the second part 1b. It is difficult to pattern the small number of masks M2, which are separated from the many fine masks M1, with high accuracy and reduced fluctuation simultaneously with the many masks M1 under the conditions for forming the many masks M1. In other words, it is difficult to reduce the width of the mask M2 while forming the many fine masks M1.

To suppress the operation of the parasitic diode at the outer perimeter part of the semiconductor device 100 at which the p-type semiconductor region 4 is located, it is favorable for the mask M2 to be wide and for the contact area between the second metal part 22b and the second part 1b to be large. On the other hand, the leakage current of the Schottky barrier diode D2 increases as the contact area between the second metal part 22b and the second part 1b increases.

As described above, for the Schottky barrier diode D2, it is not easy to reduce the leakage current by adjusting the dimension and arrangement of the p-type semiconductor region 4 from the perspective of constraints on the manufacturing method and suppressing the operation of the parasitic diode.

The semiconductor device 100 according to the embodiment includes the p⁻-type shield region 5 located below the second metal part 22b. By including the p⁻-type shield region 5, the electric field intensity at the Schottky barrier diode D2 vicinity can be reduced. As a result, the leakage current that flows through the Schottky barrier diode D2 when the semiconductor device 100 is in the off-state can be reduced. According to the embodiment, the leakage current due to the Schottky barrier diode D2 can be reduced, and the power loss of the semiconductor device 100 can be reduced.

It is favorable for the p-type impurity concentration of the p⁻-type shield region 5 to be less than the p-type impurity concentration of the p-type semiconductor region 4. As a result, the electric field intensity at the outer perimeter end of the p⁻-type shield region 5 can be relaxed, and the breakdown voltage of the semiconductor device 100 can be further increased.

The Z-direction position of the p⁻-type shield region 5 is modifiable as appropriate. If, however, the distance between the p-type semiconductor region 4 and the p⁻-type shield region 5 is too short, there is a possibility that the effect of the Schottky barrier diode D2 suppressing the operation of the parasitic diode may be reduced. If the distance between the p-type semiconductor region 4 and the p⁻-type shield region 5 is too long, the effect of the p⁻-type shield region 5 reducing the electric field intensity is reduced. It is therefore favorable for the Z-direction distance between the p-type semiconductor region 4 and the p⁻-type shield region 5 to be greater than 0.2 μm and less than 1.0 μm.

It is favorable for the first part 1a to include the first region r1 as shown in FIG. 3. When the first region r1 is included, the electrical resistance in the current path at the periphery of the p-type base region 2 can be reduced when the Schottky barrier diode D1 operates. As a result, an increase of the voltage of the p-type base region 2 can be suppressed, and the parasitic diode made of the n⁻-type drift region 1 and the p-type base region 2 does not easily operate.

Similarly, it is favorable for the second part 1b to include the third region r3 as shown in FIG. 4. When the third region r3 is included, the electrical resistance in the current path at the periphery of the p-type semiconductor region 4 can be reduced when the Schottky barrier diode D2 operates. As a result, an increase of the voltage of the p-type semiconductor region 4 can be suppressed, and the parasitic diode made of the n⁻-type drift region 1 and the p-type semiconductor region 4 does not easily operate.

The embodiment is particularly favorable for a so-called SiC device in which each semiconductor region includes silicon carbide. When each semiconductor region includes silicon carbide, crystal defects called basal plane dislocations are present in the silicon carbide crystal. When the parasitic diode operates, the recombination energy of the electrons and holes that are injected turn the basal plane dislocations into stacking faults; and the electrical characteristics of the semiconductor device degrade. For example, the leakage current may increase, the on-resistance may increase, etc. According to the embodiment, the operation of the parasitic diode can be suppressed, and so the basal plane dislocations of the silicon carbide can be prevented from growing into stacking faults. Degradation of the characteristics of the semiconductor device 100 can be suppressed, and the reliability of the semiconductor device 100 can be increased. By using silicon carbide as the semiconductor regions, the breakdown voltages of the semiconductor device 100, the Schottky barrier diode D1, and the Schottky barrier diode D2 can be increased. The leakage currents of the Schottky barrier diodes D1 and D2 also can be suppressed.

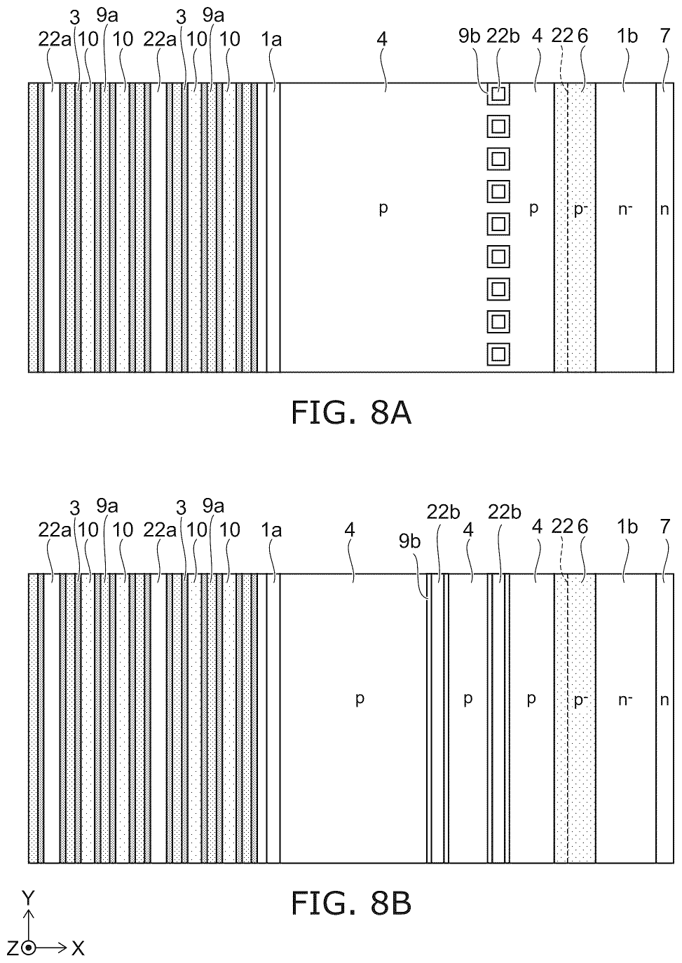

FIGS. 8A and 8B are plan views showing other examples of the semiconductor device according to the embodiment.

As shown in FIG. 8A, multiple second metal parts 22b may be arranged along the outer perimeter of the p-type semiconductor region 4. The multiple second metal parts 22b are separated from each other. As shown in FIG. 8B, multiple second metal parts 22b may be arranged in directions from the first part 1a toward the second part 1b. Each second metal part 22b surrounds the multiple first metal parts 22a along the X-Y plane. In each example shown in FIGS. 8A and 8B, the p⁻-type shield region 5 is located directly under the second metal part 22b.

As shown in FIGS. 8A and 8B, the arrangement of the second metal parts 22b is modifiable as appropriate. More favorably, the second metal part 22b surrounds the multiple first metal parts 22a along the X-Y plane as shown in FIG. 1 or FIG. 8B. As a result, a current can flow uniformly in the outer perimeter of the p-type semiconductor region 4 when the Schottky barrier diode D2 operates.

### First Modification

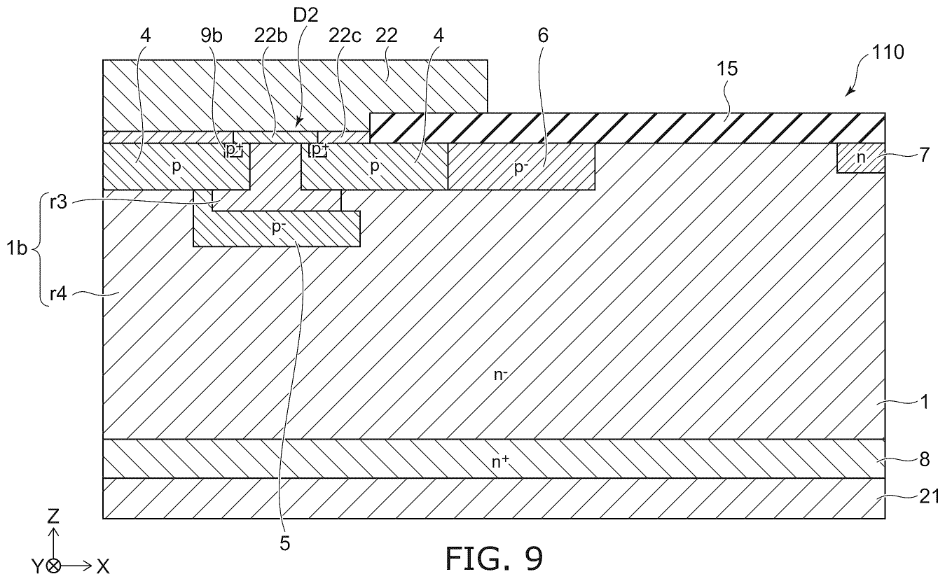

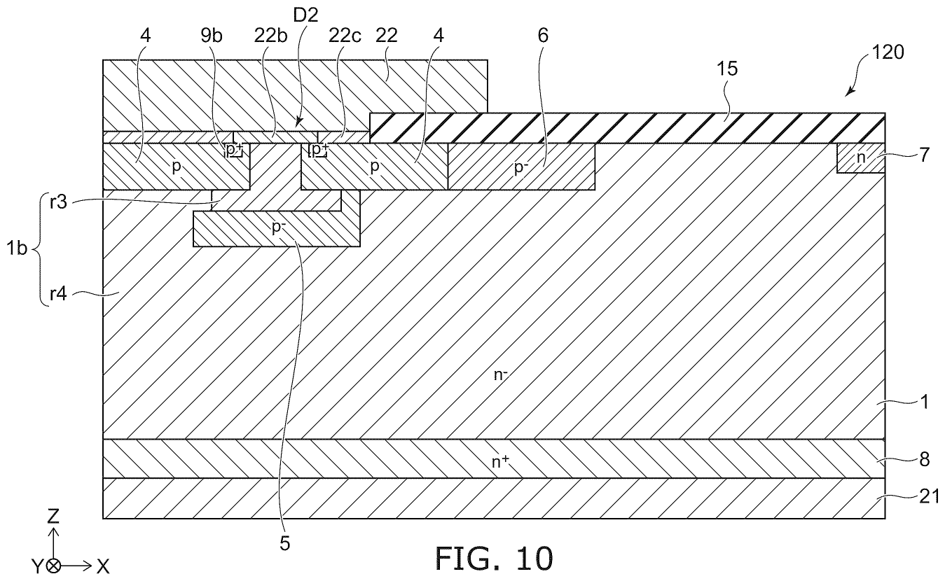

FIGS. 9 and 10 are cross-sectional views showing portions of semiconductor devices according to a first modification of the embodiment.

In the semiconductor device 100, the p⁻-type shield region 5 is separated from the p-type semiconductor region 4. In a semiconductor device 110 or 120 according to the first modification, the p⁻-type shield region 5 is connected to the p-type semiconductor region 4 as shown in FIGS. 9 and 10. The p⁻-type shield region 5 is electrically connected to the source electrode 22 via the p-type semiconductor region 4. Therefore, the potential of the p⁻-type shield region 5 is substantially equal to the potential of the source electrode 22.

The p⁻-type shield region 5 may be connected to the p-type semiconductor region 4 at the inner perimeter side of the p⁻-type shield region 5 as shown in FIG. 9, or the p⁻-type shield region 5 may be connected to the p⁻-type semiconductor region 4 at the outer perimeter side of the p⁻-type shield region 5 as shown in FIG. 10. In either case, the third region r3 is connected to the fourth region r4.

According to the first modification, the potential of the p⁻-type shield region 5 can be prevented from being in a floating state; and the operation of the semiconductor device 110 or 120 can be more stable.

### Second Modification

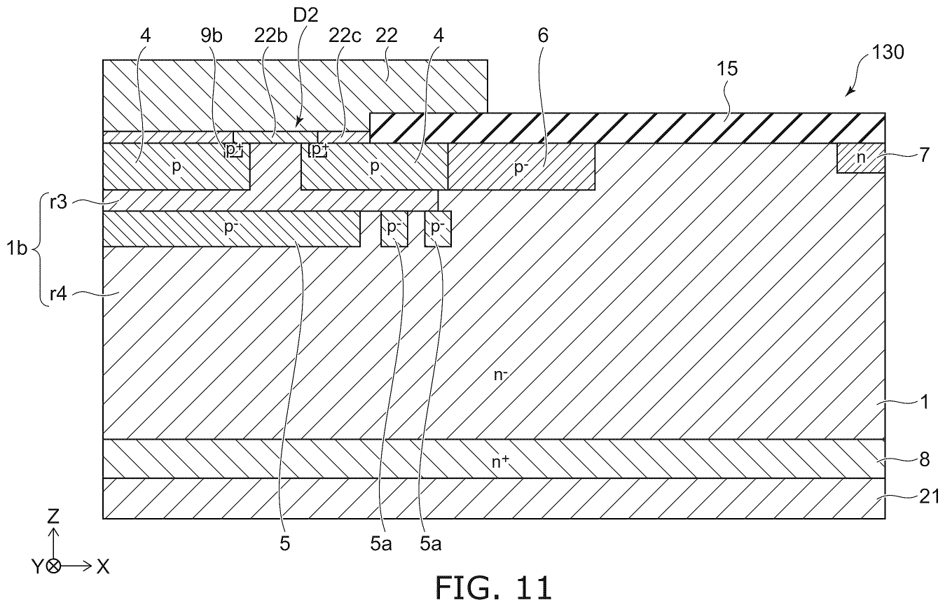

FIG. 11 is a cross-sectional view showing a portion of a semiconductor device according to a second modification of the embodiment.

The third region r3 of the semiconductor device 130 shown in FIG. 11 is wider than the third region r3 of the semiconductor device 100. The third region r3 is connected to the first region r1. Also, a p⁻-type semiconductor region 5a is located at the outer perimeter of the p-type shield region 5. The p⁻-type semiconductor region 5a is located around the p⁻-type shield region 5 along the X-Y plane. For example, multiple p⁻-type semiconductor regions 5a are arranged in directions from the first part 1a toward the second part 1b; and each p⁻-type semiconductor region 5a surrounds the p⁻-type shield region 5.

By connecting the third region r3 to the first region r1, the electrical resistance in the lateral direction from the third region r3 toward the first region r1 can be reduced. By reducing the electrical resistance, the voltage applied to the parasitic diode made of the third region r3 and the p-type semiconductor region 4 is reduced. As a result, the operation of the parasitic diode made of the n⁻-type drift region 1 and the p-type semiconductor region 4 can be suppressed even more. If the contact area between the third region r3 and the p-type semiconductor region 4 is increased in the case where the p⁻-type shield region 5 is not included, the leakage current due to the Schottky barrier diode D2 may increase. However, the semiconductor device 130 includes the p⁻-type shield region 5, and so a leakage current due to an increase of the contact area between the third region r3 and the p-type semiconductor region 4 can be suppressed. In other words, according to the second modification, the operation of the parasitic diode can be more reliably suppressed while suppressing the leakage current due to the increase of the contact area between the third region r3 and the p-type semiconductor region 4.

By including the p⁻-type semiconductor region 5a, the depletion layer can spread further toward the outer perimeter at the height at which the p--type shield region 5 is located. The electric field intensity at the outer perimeter end of the p⁻-type shield region 5 can be reduced, and the breakdown voltage of the semiconductor device 130 can be increased.

The embodiment of the invention includes the following features.

Feature 1

A semiconductor device, including:
a first electrode;
a first semiconductor region located on the first electrode, the first semiconductor region being of a first conductivity type, the first semiconductor region including a first part and a second part, the second part being located around the first part along a first plane perpendicular to a first direction, the first direction being from the first electrode toward the first part;
a second semiconductor region located on the first part, the second semiconductor region being of a second conductivity type;
a third semiconductor region located on the second semiconductor region, the third semiconductor region being of the first conductivity type;
a gate electrode facing the second semiconductor region via a gate insulating layer;
a fourth semiconductor region located on the second part, the fourth semiconductor region being positioned around the second semiconductor region along the first plane, the fourth semiconductor region being of the second conductivity type;
a second electrode located on the second, third, and fourth semiconductor regions, the second electrode including
   a first metal part contacting the first part and the second semiconductor region, the first metal part including at least one type of first element selected from the group consisting of titanium, molybdenum, and vanadium, and
   a second metal part contacting the second part and the fourth semiconductor region, the second metal part including the at least one type of first element; and
a fifth semiconductor region located lower than the fourth semiconductor region, the fifth semiconductor region being positioned directly under the second metal part, the fifth semiconductor region being of the second conductivity type.

Feature 2

The device according to feature 1, in which
a second-conductivity-type impurity concentration of the fifth semiconductor region is less than a second-conductivity-type impurity concentration of the fourth semiconductor region.

Feature 3

The device according to feature 1 or 2, in which
the fifth semiconductor region contacts the fourth semiconductor region.

Feature 4

The device according to any one of features 1 to 3, in which
a plurality of the second semiconductor regions, a plurality of the third semiconductor regions, a plurality of the gate electrodes, and a plurality of the first metal parts are arranged in a second direction perpendicular to the first direction above the first part,
the fourth semiconductor region is located around the plurality of second semiconductor regions along the first plane, and
the second metal part is located around the plurality of first metal parts along the first plane.

Feature 5

The device according to feature 4, in which
a plurality of the fourth semiconductor regions are arranged in a direction from the first part toward the second part,
the second metal part contacts the plurality of fourth semiconductor regions and a portion of the second part positioned between the plurality of fourth semiconductor regions, and
the fifth semiconductor region is positioned under the portion of the second part.

Feature 6

The device according to any one of features 1 to 5, in which
the first part includes:
   a first region contacting the second semiconductor region and the first metal part; and
   a second region positioned between the first electrode and the first region, and
a first-conductivity-type impurity concentration of the first region is greater than a first-conductivity-type impurity concentration of the second region.

Feature 7

The device according to any one of features 1 to 6, in which
the second part includes:
   a third region contacting the fourth semiconductor region and the second metal part, the third region being positioned between the fifth semiconductor region and the second metal part; and
   a fourth region positioned between the first electrode and the third region, and
a first-conductivity-type impurity concentration of the third region is greater than a first-conductivity-type impurity concentration of the fourth region.

Feature 8

The device according to any one of features 1 to 7, in which
the first semiconductor region, the second semiconductor region, the third semiconductor region, the fourth semiconductor region, and the fifth semiconductor region include silicon carbide.

In the embodiments above, the relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured by, for example, SIMS (secondary ion mass spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region located on the first electrode, the first semiconductor region being of a first conductivity type, the first semiconductor region including a first part and a second part, the second part being located around the first part along a first plane perpendicular to a first direction, the first direction being from the first electrode toward the first part;
a second semiconductor region located on the first part, the second semiconductor region being of a second conductivity type;
a third semiconductor region located on the second semiconductor region, the third semiconductor region being of the first conductivity type;
a gate electrode facing the second semiconductor region via a gate insulating layer;
a fourth semiconductor region located on the second part, the fourth semiconductor region being positioned around the second semiconductor region along the first plane, the fourth semiconductor region being of the second conductivity type;
a second electrode located on the second, third, and fourth semiconductor regions, the second electrode including
a first metal part contacting the first part and the second semiconductor region, the first metal part including at least one type of first element selected from the group consisting of titanium, molybdenum, and vanadium, and
a second metal part contacting the second part and the fourth semiconductor region, the second metal part including the at least one type of first element; and
a fifth semiconductor region located lower than the fourth semiconductor region, the fifth semiconductor region being positioned directly under the second metal part, the fifth semiconductor region being of the second conductivity type.

2. The device according to claim 1, wherein
a second-conductivity-type impurity concentration of the fifth semiconductor region is less than a second-conductivity-type impurity concentration of the fourth semiconductor region.

3. The device according to claim 1, wherein
the fifth semiconductor region contacts the fourth semiconductor region.

4. The device according to claim 1, wherein
a plurality of the second semiconductor regions, a plurality of the third semiconductor regions, a plurality of the gate electrodes, and a plurality of the first metal parts are arranged in a second direction perpendicular to the first direction above the first part,
the fourth semiconductor region is located around the plurality of second semiconductor regions along the first plane, and
the second metal part is located around the plurality of first metal parts along the first plane.

5. The device according to claim 4, wherein
a plurality of the fourth semiconductor regions are arranged in a direction from the first part toward the second part,
the second metal part contacts the plurality of fourth semiconductor regions and a portion of the second part positioned between the plurality of fourth semiconductor regions, and
the fifth semiconductor region is positioned under the portion of the second part.

6. The device according to claim 1, wherein
the first part includes:
a first region contacting the second semiconductor region and the first metal part; and
a second region positioned between the first electrode and the first region, and
a first-conductivity-type impurity concentration of the first region is greater than a first-conductivity-type impurity concentration of the second region.

7. The device according to claim 1, wherein
the second part includes:
a third region contacting the fourth semiconductor region and the second metal part, the third region being positioned between the fifth semiconductor region and the second metal part; and
a fourth region positioned between the first electrode and the third region, and
a first-conductivity-type impurity concentration of the third region is greater than a first-conductivity-type impurity concentration of the fourth region.

8. The device according to claim 7, wherein
the fifth semiconductor region contacts the fourth semiconductor region, and
a portion of the fifth semiconductor region is positioned at an inner perimeter of the third region.

9. The device according to claim 7, wherein
the fifth semiconductor region contacts the fourth semiconductor region, and
a portion of the fifth semiconductor region is positioned at an outer perimeter of the third region.

10. The device according to claim 1, wherein
the first semiconductor region, the second semiconductor region, the third semiconductor region, the fourth semiconductor region, and the fifth semiconductor region include silicon carbide.

11. The device according to claim 1, wherein
a plurality of the second metal parts are arranged along a periphery of the fourth semiconductor region.

12. The device according to claim 1, wherein
a plurality of the second metal parts are arranged in a direction from the first part toward the second part.
